(19) United States
(12) Patent Application Publication
(10) Pub. No.: US 2021/0387343 A1
(43) Pub. Date: Dec. 16, 2021

(54) INFORMATION PROCESSING DEVICE AND INFORMATION PROCESSING METHOD

(71) Applicant: Preferred Networks, Inc., Tokyo (JP)

(72) Inventors: Kentaro IMAJO, Tokyo (JP); Eiichi MATSUMOTO, Tokyo (JP); Daisuke OKANOHARA, Tokyo (JP)

(21) Appl. No.: 17/446,347

(22) Filed: Aug. 30, 2021

Related U.S. Application Data
(63) Continuation of application No. PCT/JP2020/003419, filed on Jan. 30, 2020.

(30) Foreign Application Priority Data
Mar. 1, 2019 (JP) 2019-037752

(51) Int. Cl. B25J 9/16; G06N 3/08

(52) U.S. Cl. CPC B25J 9/1671; B25J 9/161; G06N 3/084; B25J 9/163; B25J 9/1697

(57) ABSTRACT

An information processing device includes at least one memory, and at least one processor configured to perform, based on a state of a virtual world and a predetermined environment variable, a simulation with respect to the state of the virtual world, the state of the virtual world being based on an observation result of a real world, and the simulation being differentiable, and update the predetermined environment variable so that a result of the simulation approaches a changed state of the virtual world, the changed state being based on an observation result of the real world that is observed after the real world has changed.

### CROSS-REFERENCE TO RELATED APPLICATIONS

This application is a continuation application of International Application No. PCT/JP2020/003419 filed on Jan. 30, 2020, and designating the U.S., which is based upon and claims priority to Japanese Patent Application No. 2019-037752, filed on Mar. 1, 2019, the entire contents of which are incorporated herein by reference.

### BACKGROUND

### 1. Technical Field

The disclosure herein relates to an information processing device and an information processing method.

### 2. Description of the Related Art

Conventionally, a physical simulator is known as a simulation device that performs simulation using a virtual model that reproduces a real world. Generally, a physical simulator is configured to perform forward calculations.

However, it is difficult to implement a high accuracy simulation by using the above-described simulation device.

### SUMMARY

According to one aspect of the present disclosure, an information processing device includes at least one memory, and at least one processor configured to perform, based on a state of a virtual world and a predetermined environment variable, a simulation with respect to the state of the virtual world, the state of the virtual world being based on an observation result of a real world, and the simulation being differentiable, and update the predetermined environment variable so that a result of the simulation approaches a changed state of the virtual world, the changed state being based on an observation result of the real world that is observed after the real world has changed.

### BRIEF DESCRIPTION OF THE DRAWINGS

FIG. 1 is a diagram illustrating an example of an overall configuration of a simulation system;

FIG. 2 is a diagram illustrating an example of a hardware configuration of a simulation device;

FIG. 3 is a diagram illustrating an example of a functional configuration of a robot;

FIG. 4 is a diagram illustrating an example of a functional configuration of the simulation device;

FIG. 5 is a flowchart illustrating a flow of an environment variable determination process;

FIG. 6 is a diagram for explaining an operation of each unit of the simulation device that is related to the environment variable determination process;

FIG. 7 is a flowchart illustrating a flow of a difference reduction variable determination process;

FIG. 8 is a diagram for explaining an operation of each unit of the simulation device that is related to the difference reduction variable determination process;

FIG. 9 is a flowchart illustrating a flow of a robot control variable determination process; and

FIG. 10 is a diagram for explaining an operation of each unit of the simulation device that is related to the robot control variable determination process.

### DETAILED DESCRIPTION

In the following, each embodiment will be described with reference to the accompanying drawings. In the present specification and the drawings, the components having substantially the same functional configuration are referenced by the same reference numeral, and the overlapping description is omitted.

### First Embodiment

<Overall Configuration of a Simulation System>

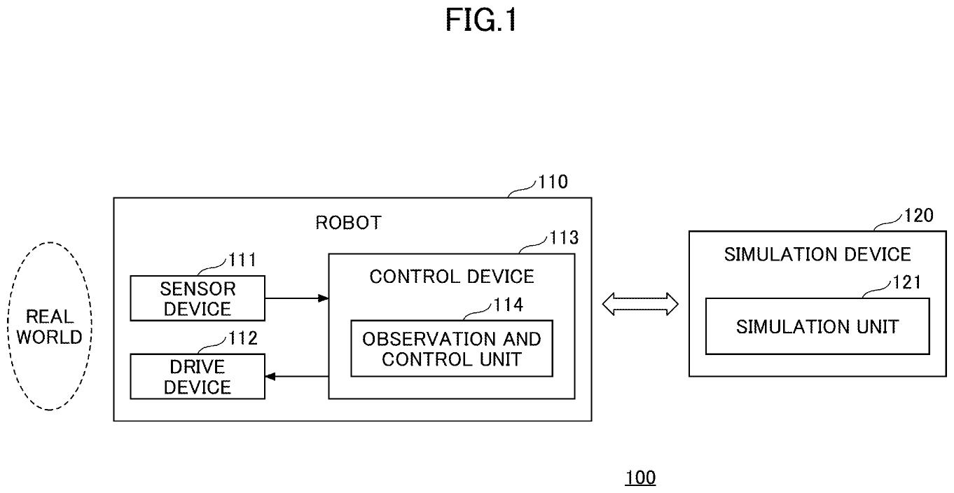

First, an overall configuration of a simulation system including an information processing device according to a first embodiment will be described. FIG. 1 is a diagram illustrating an example of the overall configuration of the simulation system.

As illustrated in FIG. 1, the simulation system 100 according to the present embodiment includes a robot 110, and a simulation device 120 as an example of an information processing device. The robot 110 and the simulation device 120 are communicatively connected.

The robot 110 includes a sensor device 111, a drive device 112, and a control device 113. The sensor device 111 observes the real world and includes, for example, a camera, a sensor, or the like. Here, the real world refers to an object on which the simulation device 120 will perform simulation. In the real world, for example, if the object to be observed is in a room, at least one of an object placed on an inner wall of the room, an object placed inside the room, or the like (e.g., a furniture, a home appliance, another robot, and the like) is included. The drive device 112 is an element that affects the real world and includes, for example, an actuator, a motor, and the like that operate respective parts of the robot 110, such as an arm, an end effector, or the like.

An observation and control program is installed in the control device 113 and when the program is executed, the control device 113 functions as an observation and control unit 114.

The observation and control unit 114 observes the real world based on an output from the sensor device 111 and generates a state of a virtual world (i.e., data in a form that can be processed by the simulation device 120) based on an observation result of the real world. The observation and control unit 114 transmits the generated state of the virtual world to the simulation device 120.

The observation and control unit 114 receives a robot control method from the simulation device 120 and controls the drive device 112 in response to transmitting the generated state of the virtual world to the simulation device 120. The robot control method includes, for example, a control item (e.g., the angle, the position, the speed, and so on) according to a type of the drive device 112 and a corresponding control amount (e.g., an angle value, a coordinate, a speed value, and so on).

A simulation program is installed in the simulation device 120, and when the simulation program is executed, the simulation device 120 functions as a simulation unit 121.

The simulation unit 121 includes a differentiable physical simulator for reproducing the real world. The simulation unit 121 includes a model of “a neural network (NN) for realization” that modifies a result of the simulation obtained when the simulation is executed using the differentiable physical simulator. Further, the simulation unit 121 includes a model of “an NN for action” that outputs the robot control method when receiving the state of the virtual world.

Specifically, the physical differentiable simulator performs the simulation, so that the simulation unit 121 outputs a result of the simulation. In the simulation unit 121, the NN for realization modifies the result of the simulation. The simulation unit 121 updates an input variable of the physical simulator, an input variable of the NN for realization, or both so that the modified result of the simulation matches the state of the virtual world received from the observation and control unit 114. Therefore, the simulation unit 121 can implement a high accuracy simulation.

Additionally, the simulation unit 121 may update the input variable of the NN for action based on a reward obtained when the robot 110 is controlled based on the robot control method output by the NN for action, for example, so as to maximize the reward. Thus, the simulation unit 121 can output the optimum robot control method when receiving the state of the virtual world.

Here, because the NNs (the NN for realization and the NN for action) perform differentiable operations, the input variables can be updated by performing backpropagation on the output results.

<Hardware Configuration of the Simulation Device>

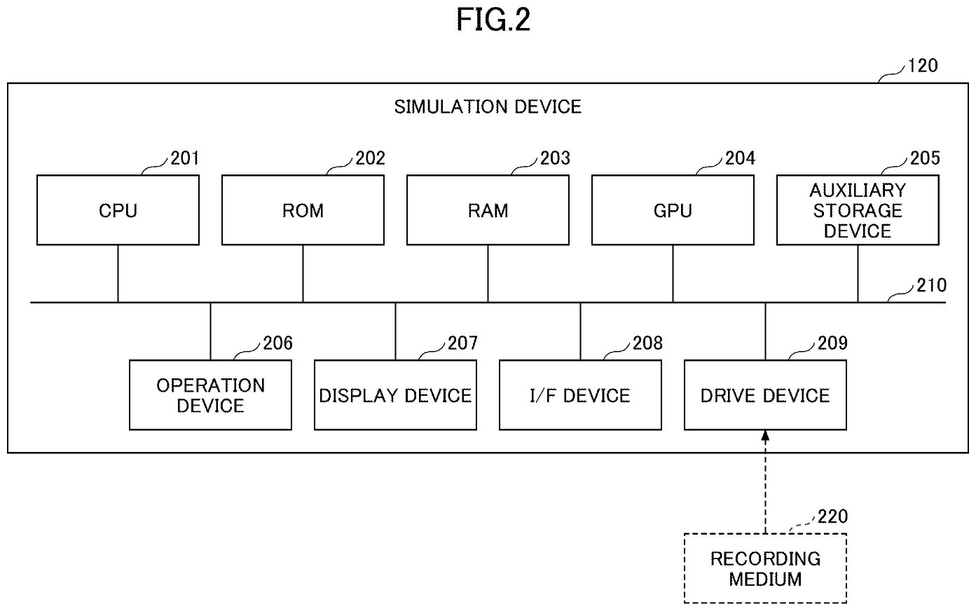

Next, a hardware configuration of the simulation device 120 will be described. FIG. 2 is a diagram illustrating an example of the hardware configuration of the simulation device.

As illustrated in FIG. 2, the simulation device 120 according to the present embodiment includes a central processing unit (CPU) 201, a read only memory (ROM) 202, and a random access memory (RAM) 203. Additionally, the simulation device 120 includes a graphics processing unit (GPU) 204. The processor (a processing circuit or a processing circuitry), such as CPU 201 and GPU 204, and a memory, such as the ROM 202 and the RAM 203, form what is called a computer.

Further, the simulation device 120 includes an auxiliary storage device 205, an operation device 206, a display device 207, an interface (I/F) device 208, and a drive device 209. Each hardware component of the simulation device 120 is interconnected through a bus 210.

The CPU 201 is an arithmetic device that executes various programs (for example, the simulation program) installed in the auxiliary storage device 205.

The ROM 202 is a non-volatile memory that functions as a main storage device. The ROM 202 stores various programs, data, and the like that are necessary for the CPU 201 to execute various programs installed in the auxiliary storage device 205. Specifically, the ROM 202 stores a boot program, such as a basic input/output system (BIOS) and an extensible firmware interface (EFI).

The RAM 203 is a volatile memory, such as a dynamic random access memory (DRAM) or a static random access memory (SRAM), and functions as a main storage device. The RAM 203 provides a workspace deployed when various programs installed in the auxiliary storage device 205 are executed by the CPU 201.

The GPU 204 is an arithmetic device for image processing. When the simulation program is executed by the CPU 201, the GPU 204 performs high-speed calculations on various image data by parallel processing. The GPU 204 includes an internal memory (a GPU memory) and temporarily stores information required to perform parallel processing on various image data.

The auxiliary storage device 205 stores various programs and various data used when various programs are executed by the CPU 201.

The operation device 206 is an input device used when an administrator of the simulation device 120 inputs various instructions to the simulation device 120. The display device 207 displays an internal state of the simulation device 120. The I/F device 208 connects and communicates with other devices (in the present embodiment, the robot 110).

The drive device 209 sets a recording medium 220. Here, the recording medium 220 includes a medium that optically, electrically, or magnetically records information, such as a CD-ROM, a flexible disk, a magneto-optical disk, or the like. Additionally, the recording medium 220 may include a semiconductor memory or the like that electrically records information, such as a ROM, a flash memory, or the like.

Here, various programs installed in the auxiliary storage device 205 are installed, for example, when the distributed recording medium 220 is set in the drive device 209 and various programs recorded in the recording medium 220 are read by the drive device 209. Alternatively, various programs installed in the auxiliary storage device 205 may be installed by being downloaded through a network, which is not illustrated.

<Functional Configuration of the Robot>

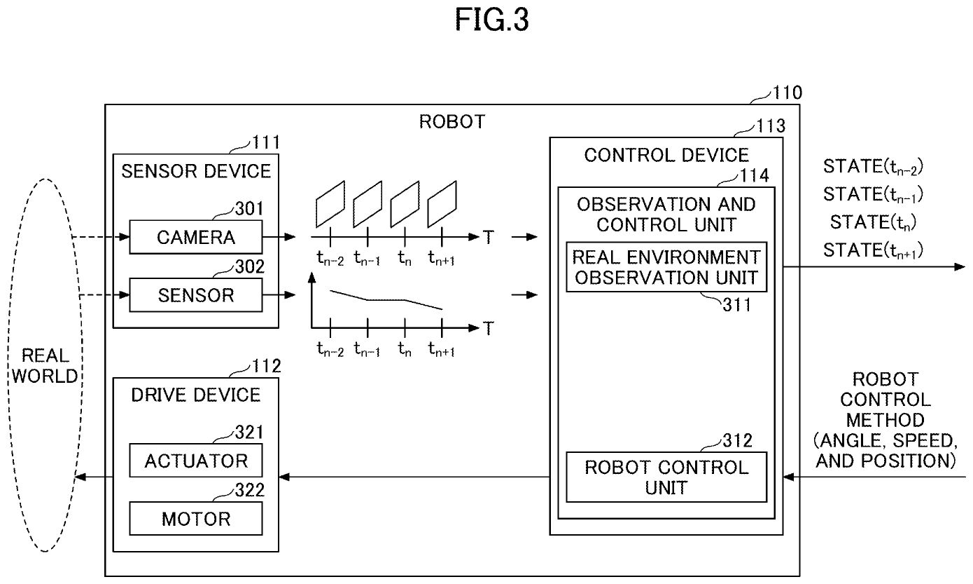

Next, a functional configuration of the robot 110 according to the present embodiment will be described. FIG. 3 is a diagram illustrating an example of the functional configuration of the robot. As illustrated in FIG. 3, the sensor device 111 includes, for example, a camera 301 and a sensor 302.

The camera 301 generates a frame image at each time (in the example of FIG. 3, from the time tₙ₋₂ to the time tₙ₊₁) by imaging the real world and notifies the control device 113 of the frame image as moving image data. The sensor 302 measures the real world to generate sensor data at each time (in the example of FIG. 3, from the time tₙ₋₂ to the tₙ₊₁) and notifies the control device 113 of the sensor data.

The drive device 112 includes an actuator 321 and a motor 322. The actuator 321 and the motor 322 affect the real world and change the real world, for example, by operating each part of the robot 110 under the control of the control device 113.

The observation and control unit 114 of the control device 113 includes a real environment observation unit 311 and a robot control unit 312. The real environment observation unit 311 acquires the moving image data and the sensor data from the sensor device 111 and quantifies the real world at each time (in the example of FIG. 3, from the time tₙ₋₂ to the time tₙ₊₁). As an example, a case of performing a task in which the robot 110 grasps an object and moves the object to a predetermined position will be described. In this case, for example, the real environment observation unit 311 acquires the moving image data that images a state in which the robot 110 grasps the object, and calculates the position and angle of the object, and the position and angle of the end effector of the robot 110 that grasps the object, in each frame image. Thus, for example, the real environment observation unit 311 can quantitatively identify whether the robot 110 can grasp the object correctly.

Additionally, the real environment observation unit 311 acquires, for example, the position and angle of the arm of the robot 110 that are detected by the sensor 302 in a state in which the robot 110 grasps the object and normalizes the position and angle. Consequently, the real environment observation unit 311 can, for example, quantitatively identify what kind of action has been performed by the robot 110 to grasp the object.

As described, by quantifying the real world, the real environment observation unit 311 generates data indicating a state of the virtual world at each time. The data is preferably in a form that can be processed by the simulation device 120 which will be utilized later. In the present embodiment, the state of the virtual world at each time is expressed as, for example, the state (tₙ₋₂) to the state (tₙ₊₁). Hereinafter, data indicating a state is simply described as a “state”. The real environment observation unit 311 transmits the state of the virtual world at each time to the simulation device 120.

Additionally, the real environment observation unit 311 may be configured to transmit, to the simulation device 120, the moving image data captured by the camera 301 or the sensor data measured by the sensor 302 itself as the state of the virtual world at each time.

The robot control unit 312 receives the robot control method from the simulation device 120 and controls the drive device 112. As described above, the robot control method includes, for example, the angle, the speed, the position, and the like as control items. The robot control unit 312 controls the actuator 321, the motor 322, and the like based on a control amount corresponding to the robot control method.

<Functional Configuration of the Simulation Device>

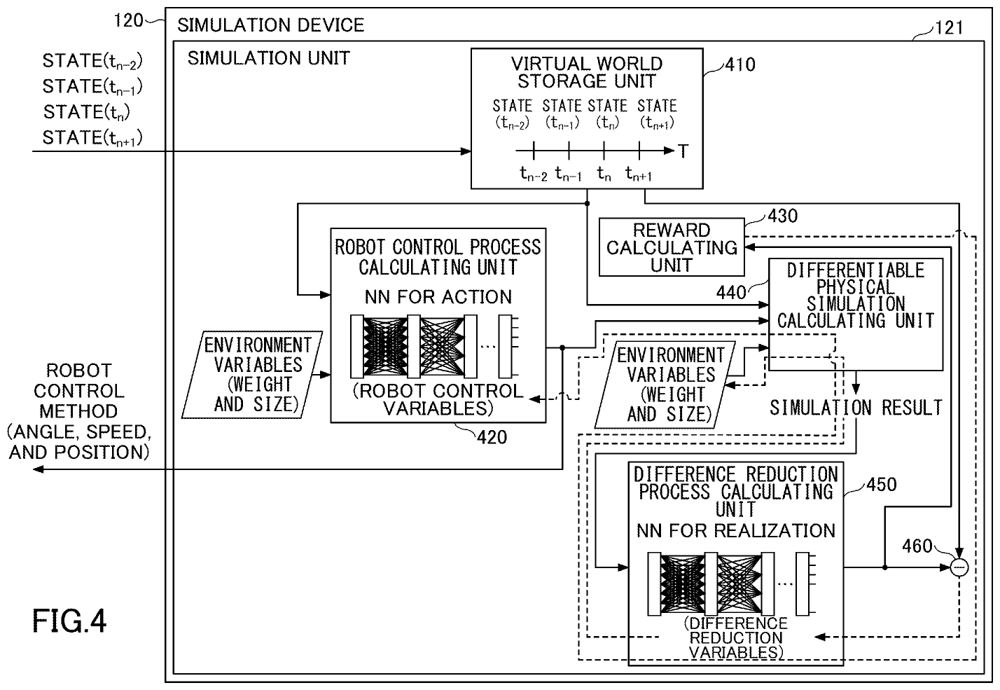

Next, a functional configuration of the simulation device will be described. FIG. 4 is a diagram illustrating an example of the functional configuration of the simulation device. As illustrated in FIG. 4, the simulation unit 121 according to the present embodiment includes, for example, a virtual world storage unit 410, a robot control process calculating unit 420, a reward calculating unit 430, a differentiable physical simulation calculating unit 440, a difference reduction process calculating unit 450, and a difference unit 460.

The virtual world storage unit 410 acquires and stores the state of the virtual world at each time that is transmitted from the real environment observation unit 311.

The robot control process calculating unit 420 includes a model of the NN for action. The robot control process calculating unit 420 outputs the robot control method upon inputting, for example, a state of the virtual world at a target time (for example, the time tₙ) (the state (tₙ)) and environment variables (physical quantities representing the properties of an object in the real world (the weight, the size, and the like)). In the present embodiment, the environment variables input to the robot control process calculating unit 420 are the same as environment variables input to the differentiable physical simulation calculating unit 440, which will be described later.

Here, the robot control process calculating unit 420 may function as a second training unit. Specifically, in response to the output of the robot control method, the robot control process calculating unit 420 performs backpropagation based on a reward of a changed state to be observed after the state of the virtual world changes (for example, the state (tₙ₊₁)), for example, so as to maximize the reward. Consequently, the robot control process calculating unit 420 updates a robot control variable (i.e., one of the NN input variables for action). In this manner, the robot control process calculating unit 420 is trained and a trained second training unit is generated.

The reward calculating unit 430 is an example of a calculating unit and calculates the reward based on the changed state of the virtual world. The reward calculated by the reward calculating unit 430 quantifies how good or bad the control of the robot 110 performed based on the robot control method that is output by the robot control process calculating unit 420.

The differentiable physical simulation calculating unit 440 is a physical simulator in which each calculation is differentiable (in other words, the physical simulator is constructed in a differentiable framework) and functions as an executing unit.

Specifically, for example, the differentiable physical simulation calculating unit 440 acquires the robot control method from the robot control process calculating unit 420. Additionally, the differentiable physical simulation calculating unit 440 performs simulation by, for example, using the state of the virtual world at the target time (for example, the time tₙ) (i.e., the state (tₙ)), the acquired robot control method, and the environment variables, as inputs. Further, the differentiable physical simulation calculating unit 440 outputs, for example, the state of the virtual world at the time next to the target time (for example, the time tₙ₊₁) (i.e., the state (tₙ₊₁ )), as a result of the simulation.

Here, the differentiable physical simulation calculating unit 440 may also function as an updating unit. Specifically, for example, the differentiable physical simulation calculating unit 440 performs backpropagation with respect to the result of the simulation that is obtained by using the state of the virtual world at each time and the robot control method output based on the state at each time as inputs. Consequently, the differentiable physical simulation calculating unit 440 updates the environment variable that is one of the input variables.

At this time, the differentiable physical simulation calculating unit 440 updates the environment variable so that the simulation result matches the changed state of the virtual world that is received from the observation and control unit 114. When the environment variable that is input to the differentiable physical simulation calculating unit 440 is updated, the environment variable that is input to the robot control process calculating unit 420 is preferably updated accordingly. For example, the environment variable that is input to the robot control process calculating unit 420 is preferably updated to a value equal to the value of the environment variable that is input to the differentiable physical simulation calculating unit 440. Consequently, the robot control process calculating unit 420 can output the robot control method based on the latest environment variable.

The difference reduction process calculating unit 450 includes a model of the NN for realization. The difference reduction process calculating unit 450 receives the result of the simulation of the differentiable physical simulation calculating unit 440 as an input and outputs a modified result of the simulation.

Here, the difference reduction process calculating unit 450 may function as a first training unit. Specifically, the difference reduction process calculating unit 450 can update a difference reduction variable that is one of the NN input variables for realization by performing backpropagation with respect to the modified result of the simulation that is obtained by using the various simulation results as inputs. In this manner, the difference reduction process calculating unit 450 is trained and a trained first training unit is generated.

That is, the difference reduction process calculating unit 450 updates the difference reduction variable so that the result of the simulation matches the changed state of the virtual world that is received from the observation and control unit 114, thereby serving as a unit that causes the result of the simulation to approximate to the real world, and preferably match the real world.

This is because it is difficult for the differentiable physical simulation calculating unit 440 to completely define the properties of the object in the real world as environment variables in advance, and normally the result of the simulation does not match the changed state of the virtual world. In other words, the difference reduction process calculating unit 450 serves as a unit that reduces error of the result of the simulation due to not being defined as environment variables, for example, an unknown property of the object.

The difference unit 460 contrasts the modified result of the simulation with the changed state of the virtual world (i.e., the state (tₙ₊₁)) that is received from the observation and control unit 114, and determines whether a result of the contrast satisfies a predetermined condition. Here, the modified result of the simulation, for example, is converted into a form that can be compared with the changed state of the virtual world that is received from the observation and control unit 114 and then can be contrasted in the difference unit 460.

For example, as the changed state of the virtual world (i.e., the state (tₙ₊₁)), the frame image of the moving image data is assumed to be already stored in the virtual world storage unit 410. In this case, the difference unit 460 may perform the contrast after the modified result of the simulation is converted to an image format, for example.

Additionally, it is assumed that the normalized position and angle of an arm of the robot 110 are stored in the virtual world storage unit 410 as the changed state of the virtual world (the state (tₙ₊₁)). In this case, the difference unit 460 may contrast the modified result of the simulation by converting the modified result of the simulation into a format of the normalized position and angle, for example.

Here, the environment variable and the difference reduction variable are updated until the result of the contrast performed by the difference unit 460 satisfies the predetermined condition (for example, the difference is zero or is less than a predetermined threshold value).

<Processing Flow in the Simulation System>

Next, a processing flow in the simulation system 100 will be described. As can be seen from the above description, a process performed in the simulation system 100 can be roughly classified into the following three processing steps (the process of updating and determining three input variables).
an environment variable determination process of updating and determining the environment variables
a difference reduction variable determination process of updating and determining the difference reduction variables
a robot control variable determination process of updating and determining the robot control variables In the following, these processes will be described with reference to the corresponding operation of each unit (the operations of respective units related to these processes among the units of the functional configuration illustrated in FIG. 4).

(1) Environment Variable Determination Process

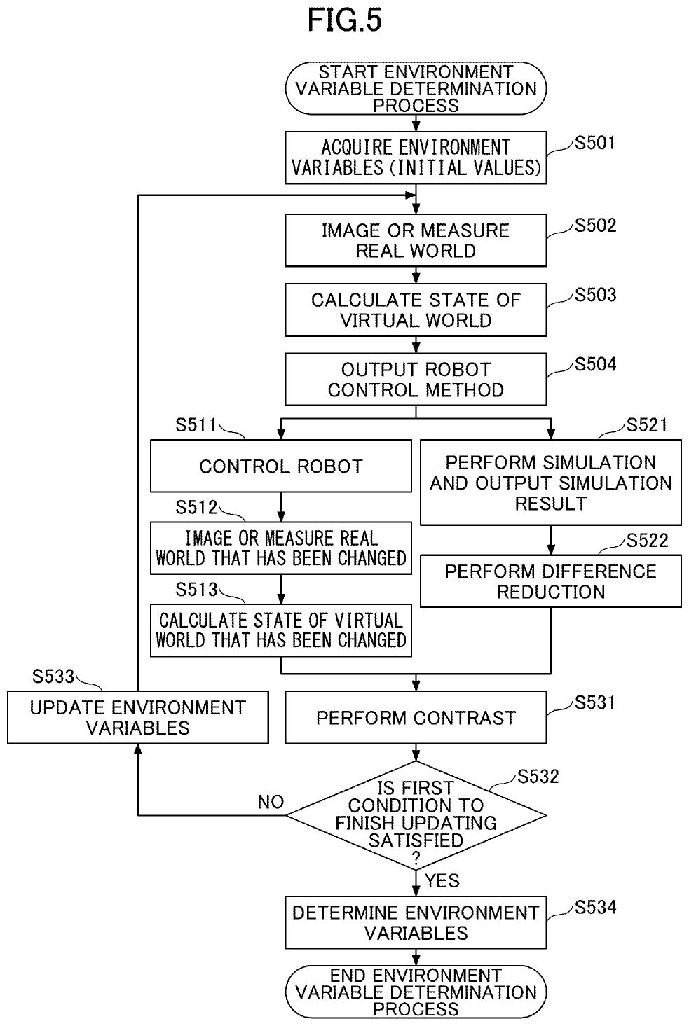

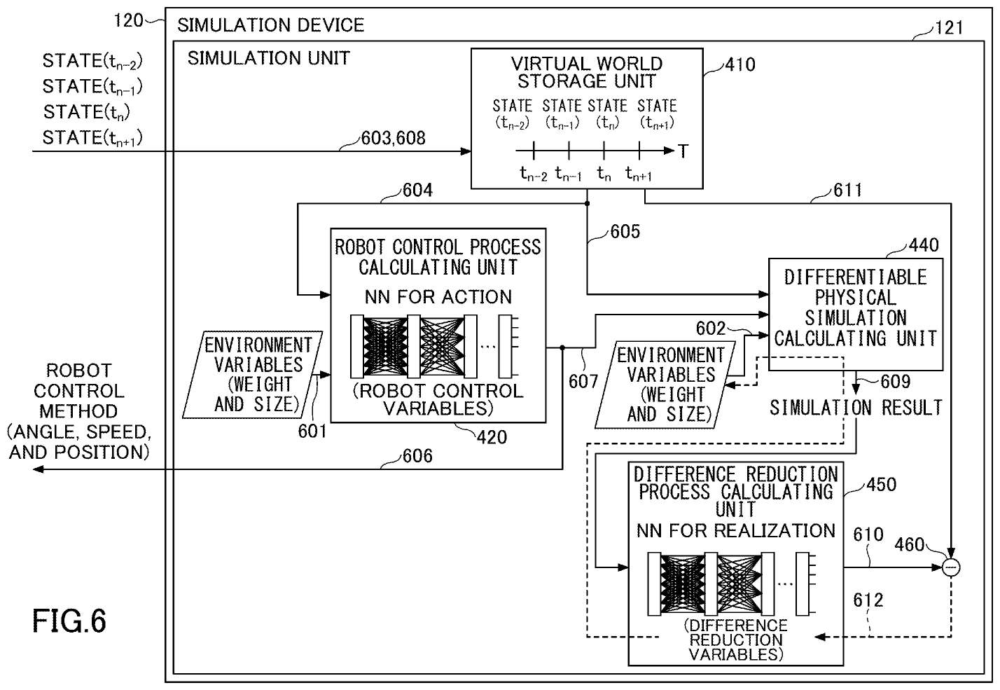

First, the environment variable determination process will be described with reference to FIG. 5 and FIG. 6. FIG. 5 is a flowchart illustrating an example of a flow of the environment variable determination process. FIG. 6 is a diagram for explaining an example of an operation of each unit of the simulation device related to the environment variable determination process. In the following, the flowchart of FIG. 5 will be described with reference to FIG. 6. In performing the environment variable determination process, the robot control variables of the robot control process calculating unit 420 and the difference reduction variables of the difference reduction process calculating unit 450 are assumed to be fixed to predetermined values. The following description will be made along a case in which the robot 110 performs a task of grasping an object and moving the object to a predetermined position, as a specific example.

In step S501, the robot control process calculating unit 420 and the differentiable physical simulation calculating unit 440 acquire the environment variables (initial values) (see the arrows 601 and 602 in FIG. 6).

In step S502, the sensor device 111 images or measures the real world. For example, the sensor device 111 images or measures a state in which the robot 110 grasps the object.

In step S503, the observation and control unit 114 calculates the state of the virtual world and transmits the calculated state to the simulation device 120 (see the arrow 603 of FIG. 6). Consequently, as illustrated in FIG. 6, the state of the virtual world (i.e., the state (tₙ)) is stored in the virtual world storage unit 410 in association with the target time (here, the time tₙ).

In step S504, the robot control process calculating unit 420 receives the state of the virtual world at the target time (i.e., the time tₙ) (i.e., the state (tₙ)) and the environment variables (here, the initial values) (see the arrows 601 and 604 in FIG. 6) and outputs the robot control method. Here, the robot control process calculating unit 420 outputs the robot control method to the control device 113 of the robot 110 and the differentiable physical simulation calculating unit 440 (see the arrows 606 and 607 of FIG. 6). Here, for example, the robot control process calculating unit 420 outputs a robot control method for the robot 110 to lift the grasped object.

In step S511, the control device 113 of the robot 110 controls the drive device 112 based on the robot control method. This causes the robot 110 to lift the grasped object. At this time, it is assumed that the force of the robot 110 to grasp the object is small relative to the weight of the object, and the object is shifted when the robot 110 lifts the object.

In step S512, the sensor device 111 images or measures the real world that has changed due to the drive device 112 that is controlled. Specifically, a state in which the object is lifted by the robot 110 with the object being shifted is imaged or measured.

In step S513, the observation and control unit 114 calculates the state of the virtual world that has changed in response to, for example, imaging or measuring the real world that has changed, and transmits the calculated state to the simulation device 120 (see the arrow 608 in FIG. 6). Consequently, the virtual world storage unit 410 stores the state (tₙ₊₁) that is the state of the virtual world at the time tₙ₊₁.

In step S521, the state of the virtual world at the target time (the time tₙ) (i.e., the state (tₙ)), the robot control method, and the environment variables (here, the initial values) are input to the differentiable physical simulation calculating unit 440 (see the arrows 602, 605, and 607 in FIG. 6). Specifically, the robot control method for the robot 110 to lift the grasped object is input to the differentiable physical simulation calculating unit 440. Additionally, for example, the weight of the object (here, the initial value) is input to the differentiable physical simulation calculating unit 440 as an environment variable.

Consequently, the differentiable physical simulation calculating unit 440 outputs a result of the simulation (see the arrow 609 of FIG. 6).

In step S522, the difference reduction process calculating unit 450 receives the result of the simulation of the differentiable physical simulation calculating unit 440 and outputs a result of the simulation that has been modified (see the arrow 610 of FIG. 6). Here, for example, as the modified result of the simulation, the difference reduction process calculating unit 450 outputs a state in which the robot 110 has lifted the grasped object without the grasped object being shifted.

In step S531, the difference unit 460 contrasts the modified result of the simulation with the changed state of the virtual world (i.e., the state (tₙ₊₁)) (see the arrows 610 and 611 in FIG. 6).

In step S532, the difference unit 460 determines whether a result of the contrast satisfies a first condition to finish updating. In step S532, if it is determined that the first condition to finish updating is not satisfied (No in step S532), the process proceeds to step S533.

As described above, in step S512, the state in which the object is lifted by the robot 110 with the object being shifted is imaged or measured, and in step S513, the state is stored as the changed state of the virtual world (i.e., the state (tₙ₊₁)). In step S522, as the modified result of the simulation, the state in which the robot 110 lifts the grasped object without the grasped object being shifted is output. Therefore, the difference unit 460 determines that the first condition to finish updating is not satisfied.

In step S533, the difference reduction process calculating unit 450 and the differentiable physical simulation calculating unit 440 perform backpropagation in accordance with the result of the contrast, and update the environment variables (see the arrow 612 of FIG. 6). Specifically, the differentiable physical simulation calculating unit 440 updates the weight of the object as the environment variable. Here, when the difference reduction process calculating unit 450 performs the backpropagation, the difference reduction variables are not updated. Additionally, the model parameters of the differentiable physical simulation calculating unit 440 are not updated.

In step S533, when the environment variables are updated by the differentiable physical simulation calculating unit 440, the process returns to step S502.

In step S532, when it is determined that the first condition to finish updating is satisfied (Yes in step S532), the process proceeds to step S534, the current environment variables are determined as physical quantities representing the real-world environment, and the environment variable determination process is finished.

(2) Difference Reduction Variable Determination Process

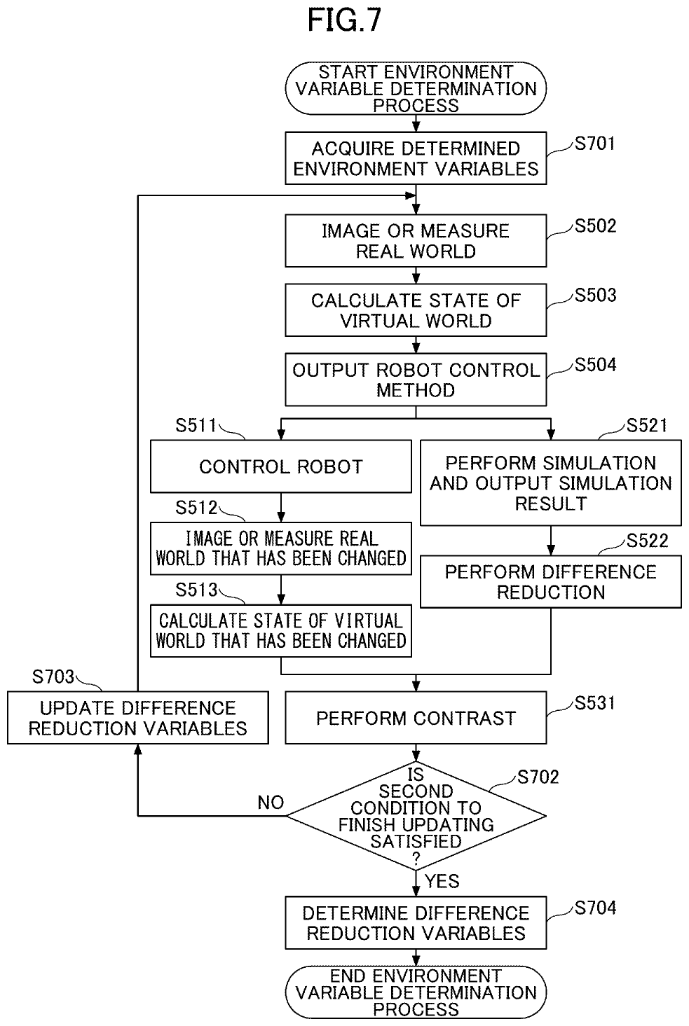

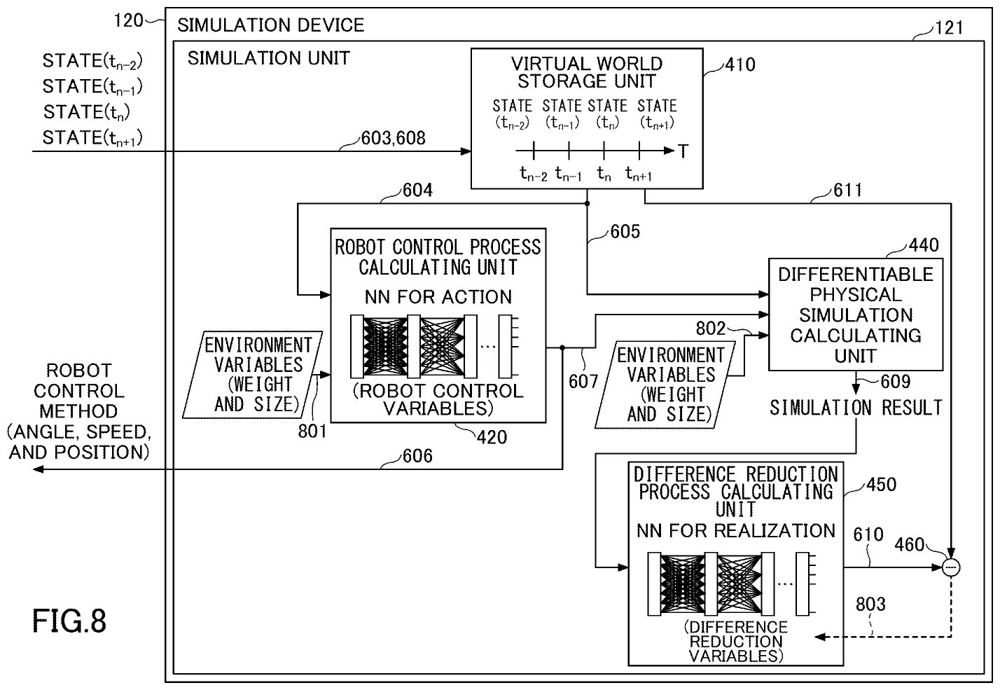

Next, a difference reduction variable determination process will be described with reference to FIG. 7 and FIG. 8. FIG. 7 is a flowchart illustrating an example of a flow of the difference reduction variable determination process. FIG. 8 is a diagram for explaining an example of an operation of each unit of the simulation device that is related to the difference reduction variable determination process. In the following, the flowchart of FIG. 7 will be described with reference to FIG. 8. In performing the difference reduction variable determination process, the robot control variables of the robot control process calculating unit 420 are assumed to be fixed to predetermined values. The environment variables determined by the environment variable determination process illustrated in FIG. 5 are assumed to be used.

In step S701, the robot control process calculating unit 420 and the differentiable physical simulation calculating unit 440 acquire the determined environment variables (see the arrows 801 and 802 in FIG. 8). Specifically, the robot control process calculating unit 420 and the differentiable physical simulation calculating unit 440 acquire the determined weight of the object as the determined environment variable.

Step S502 to step S531 are substantially the same as step S502 to step S531 of FIG. 5, and therefore, the description is omitted here.

However, in step S504, the robot control process calculating unit 420 outputs the robot control method for lifting the grasped object based on the determined object weight. This reduces the shift amount caused when the object is lifted by the robot 110 in comparison with the shift amount caused before the weight of the object is determined. That is, in step S512, the robot 110 images or measures a state in which the object is lifted while being slightly shifted, and in step S513, the state is stored as the changed state of the virtual world.

With respect to the above, in step S522, the difference reduction process calculating unit 450 outputs, as the modified result of the simulation, the state in which the robot 110 has lifted the grasped object without the grasped object being shifted, for example.

In step S702, the difference unit 460 determines whether the result of the contrast satisfies a second condition to finish updating. In step S702, if it is determined that the second condition to finish updating is not satisfied (No in step S702), the process proceeds to step S703.

As described above, in step S513, the state in which the object is lifted with the object being slightly shifted is stored as the state of the virtual world that has changed. In step S522, as the modified result of the simulation, the state in which the robot 110 has lifted the grasped object without the grasped object being shifted is output. Thus, it is determined that the difference unit 460 does not satisfy the second condition to finish updating. As described, the second condition to finish updating is not satisfied because an unknown property of the object that is not defined as the environment variable (here, the coefficient of friction of a surface of the object) is not reflected in the result of the simulation.

In step S703, the difference reduction process calculating unit 450 performs backpropagation in accordance with the result of the contrast, and updates the difference reduction variables (see the arrow 803 of FIG. 8). Consequently, the difference reduction process calculating unit 450 modifies the error of the result of the simulation (the error caused by a friction coefficient of the surface of the object that is not defined as the environment variable).

In step S702, if it is determined that the second condition to finish updating is satisfied (Yes in step S702), the process proceeds to step S704.

In step S704, the difference reduction process calculating unit 450 determines the current difference reduction variables as the difference reduction variables of the difference reduction process calculating unit 450 and ends the difference reduction variable determination process.

(3) Robot Control Variable Determination Process

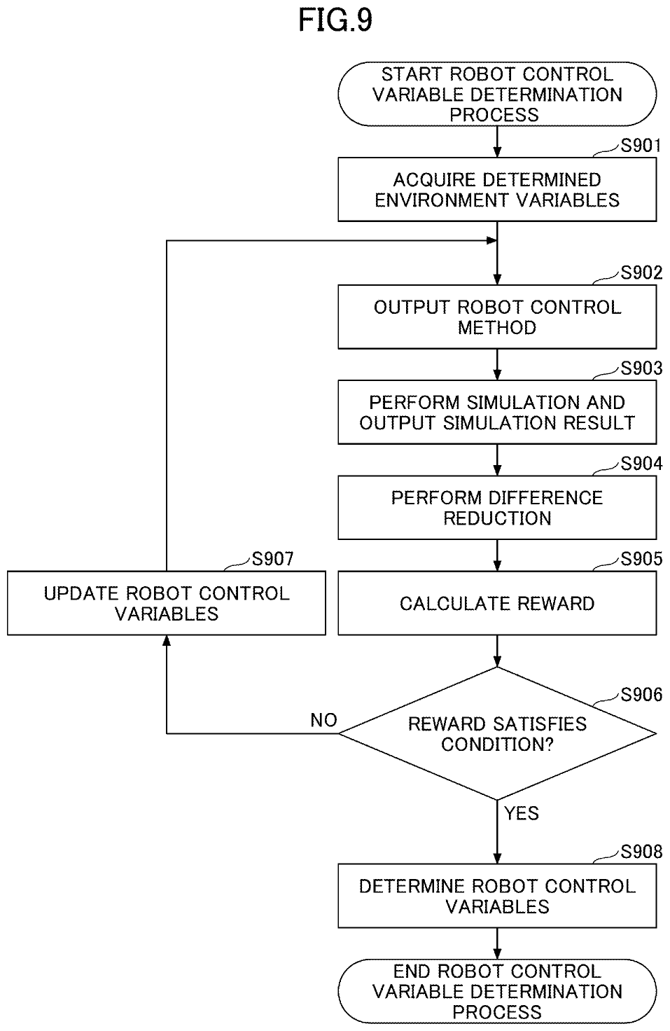

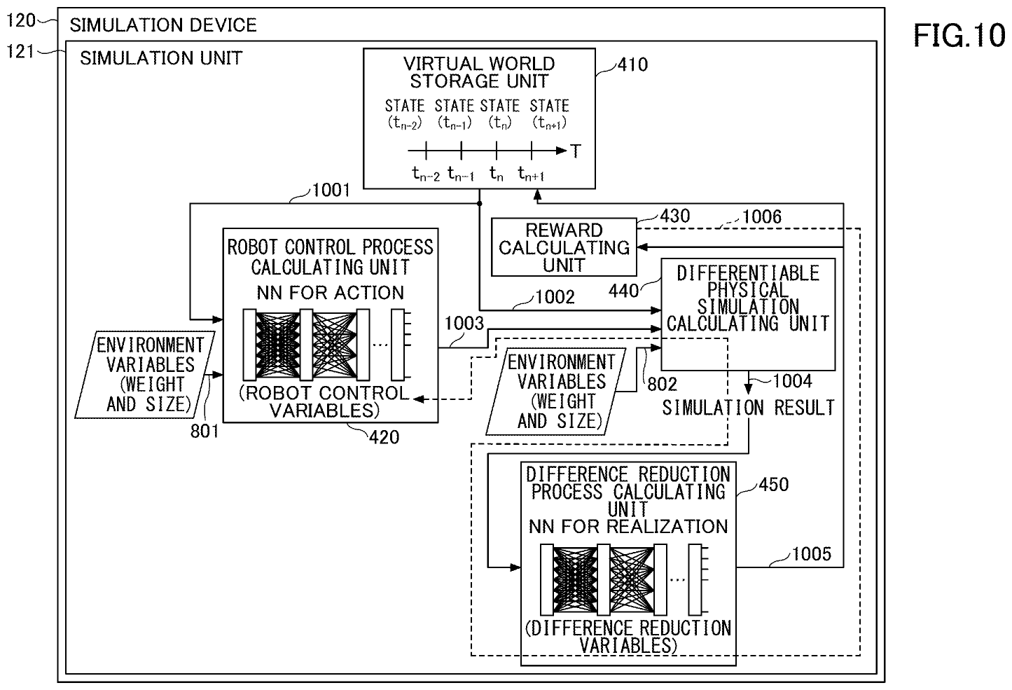

Next, a robot control variable determination process will be described with reference to FIG. 9 and FIG. 10. FIG. 9 is a flowchart illustrating a flow of the robot control variable determination process. FIG. 10 is a diagram for explaining an operation of each unit of the simulation device that is related to the robot control variable determination process. In the following, the flowchart of FIG. 9 will be described with reference to FIG. 10. In performing the robot control variable determination process, the environment variables determined by the environment variable determination process illustrated in FIG. 5 are used as the environment variables. The difference reduction variables determined by the difference reduction variable determination process illustrated in FIG. 7 are used as the difference reduction variables. In starting the robot control variable determination process, it is assumed that an initial state is previously stored in the virtual world storage unit 410.

In step S901, the robot control process calculating unit 420 and the differentiable physical simulation calculating unit 440 acquire the determined environment variables (see the arrows 801 and 802 in FIG. 10).

In step S902, the state of the virtual world at the target time (for example, the time tₙ) (i.e., the state (tₙ)) and the environment variables are input to the robot control process calculating unit 420 (see the arrows 801 and 1001 of FIG. 10). Consequently, the robot control process calculating unit 420 outputs the robot control method to the differentiable physical simulation calculating unit 440 (see the arrow 1003 in FIG. 10).

In step S903, the differentiable physical simulation calculating unit 440 receives the state of the virtual world at the target time (the time tₙ) (i.e., the state (tₙ)), the robot control method, and the environment variables (see the arrows 802, 1002, and 1003 in FIG. 10). Consequently, the differentiable physical simulation calculating unit 440 outputs the result of the simulation (see the arrow 1004 in FIG. 10).

In step S904, the difference reduction process calculating unit 450 receives the result of the simulation of the differentiable physical simulation calculating unit 440 and outputs the result of the simulation that has been modified (see the arrow 1005 of FIG. 10). The modified result of the simulation (for example, the state of the virtual world (the state (tₙ₊₁)) at the time tₙ₊₁) is stored in the virtual world storage unit 410 and input to the reward calculating unit 430.

In step S905, the reward calculating unit 430 calculates a reward based on the modified result of the simulation. Specifically, a parameter, defined such that the score increases if the robot 110 outputs the state in which the grasped object is lifted without the grasped object being shifted as the modified result of the simulation, is calculated as the reward. Additionally, a parameter, defined such that the score increases as the object lifted without the object being shifted approaches a predetermined position, may be calculated as the reward.

In step S906, the reward calculating unit 430 determines whether the calculated reward satisfies a predetermined condition (i.e., whether the calculated reward is maximum). If the reward calculated in step S906 does not satisfy the predetermined condition (No in step S906), the process proceeds to step S907.

In step S907, the difference reduction process calculating unit 450, the differentiable physical simulation calculating unit 440, and the robot control process calculating unit 420 perform backpropagation based on the calculated reward, and update the robot control variables (see the arrow 1006 of FIG. 10). Specifically, the backpropagation is performed to maximize the calculated reward, and the robot control variables are updated. Subsequently, the robot control process calculating unit 420 returns to step S902.

If the reward calculated in step S906 satisfies the predetermined condition (Yes in step S907), the process proceeds to step S908.

In step S908, the robot control process calculating unit 420 determines the current robot control variables as the robot control variables of the robot control process calculating unit 420 and ends the robot control variable determination process.

As described, according to the simulation unit 121, the robot control variable determination process can be performed without actually operating the robot 110.

Additionally, by performing the robot control variable determination process and optimizing the robot control variables, the robot control process calculating unit 420 can transmit the optimum robot control method to the robot 110 subsequently every time when the robot control process calculating unit 420 receives the changed state of the virtual world.

<Summary>

As can be seen from the above description, the simulation device 120, which is an example of the information processing device according to the first embodiment is configured to:
acquire a state of the virtual world calculated based on an observation result of the real world
acquire a robot control method used to control a robot that affects the real world.
perform a differentiable simulation with respect to a changed state of the virtual world by using the state of the virtual world and the robot control method as inputs under predetermined environment variables to output a result of the simulation
update the environment variables so that the output result of the simulation approaches the changed state of the virtual world that is calculated from an observation result of the real world that is changed by the robot controlled under the robot control method.

Thus, the simulation device 120 can reproduce the properties of the object in the real world as the environment variables, and a result of the physical simulator (the differentiable physical simulation calculating unit 440) can be made closer to the real world. As a result, high accuracy simulation can be implemented.

Additionally, the simulation device 120, which is an example of the information processing device according to the first embodiment is configured to:
perform a differentiable simulation upon inputting the state of the virtual world and the robot control method under the updated environment variables to output a result of the simulation
modify the output result of the simulation and output the modified result of the simulation
update difference reduction variables so that the output modified result of the simulation approaches a changed state of the virtual world that is calculated from an observation result of the real world that is changed by the robot controlled under the robot control method, that is, perform training with respect to a correspondence relation between the output result of the simulation and the modified simulation result.

Thus, according to the simulation device 120, the result of the simulation that is output from the physical simulator (the differentiable physical simulation calculating unit 440) is modified and the modified result of the simulation can be made closer to the real world. As a result, the improved accuracy of the simulation can be implemented.

Further, the simulation device 120, which is an example of the information processing device according to the first embodiment is configured to:
output a robot control method upon inputting the state of the virtual world under the updated environment variables
perform a differentiable simulation upon inputting the state of the virtual world and the output robot control method under the updated environment variables to output a result of the simulation, and calculate a reward with modifying the result of the output simulation under the updated difference reduction variables
perform training with respect to the correspondence relation between the state of the virtual world and the robot control method based on the calculated reward.

Consequently, the simulation device 120 can perform training with respect to the correspondence relation between the state of the virtual world and the robot control method without actually operating the robot, and can optimize the robot control variables. Additionally, the optimum robot control method can be output based on the state of the virtual world.

### Second Embodiment

In the first embodiment described above, a case, in which the simulation system 100 performs each process in the order of the environment variable determination process, the difference reduction variable determination process, and the robot control variable determination process, has been described. However, the order of the processes performed by the simulation system 100 is not limited to this. For example, after each process is performed in the order of the environment variable determination process, the difference reduction variable determination process, and the robot control variable determination process, the environment variable determination process or the difference reduction variable determination process may be performed again.

In the first embodiment described above, the above description assumes that the real environment observation unit 311 is disposed in the control device 113 of the robot 110. However, the real environment observation unit 311 may be disposed in the simulation unit 121 of the simulation device 120.

In the first embodiment described above, the above description assumes that the simulation device 120 is implemented in one computer, but the simulation device 120 may be implemented in one or more computers. Additionally, if the simulation device 120 is implemented in multiple computers, the multiple computers may be installed at multiple locations separately.

In the first embodiment described above, the above description assumes that the simulation device 120 causes a general-purpose computer to execute various programs to implement the simulation unit 121. However, the method of implementing the simulation unit 121 is not limited to this.

For example, the simulation unit 121 may be implemented by a dedicated electronic circuit (i.e., hardware), such as an integrated circuit (IC) that implements a processor, a memory, or the like. In this case, multiple components may be implemented in one electronic circuit, a single component may be implemented in multiple electronic circuits, and a component may be implemented in one-to-one correspondence with an electronic circuit.

### Other Embodiments

In the above-described first and second embodiments, an example of performing a task, in which the robot 110 grasps an object and moves the object to a predetermined position, has been described. However, the task performed by the robot 110 is not limited to this. For example, a task, such as moving an object, suctioning an object like a vacuum cleaner, or moving the robot 110 itself may be performed.

In the above-described first and second embodiments, a case in which the real world changed with operating the robot 110 based on the robot control method output from the robot control process calculating unit 420 has been described.

However, the simulation device 120 described above can be also applied to a case in which the real world changes without operating the robot 110. However, when the simulation device 120 is applied to such a case, the robot control process calculating unit 420 and the reward calculating unit 430 are not required. That is, the simulation unit 121 may be configured by the virtual world storage unit 410, the differentiable physical simulation calculating unit 440, and the difference reduction process calculating unit 450.

Here, a case in which the real world changes without operating the robot 110 may include, for example, a case in which a meteorological simulation is performed by using the differentiable physical simulation calculating unit 440. Specifically, the high accuracy simulation can be implemented by training the difference reduction process calculating unit 450 so that a simulation result obtained upon inputting the current weather condition approaches, or preferably matches the next weather condition.

It should be noted that the present invention is not limited to the above-described configurations, such as the configurations described in the above-described embodiments, and combinations with other elements. In these respects, modifications can be made within the scope of the invention without departing from the spirit of the invention, and the configuration can be appropriately determined in accordance with the application form. For example, another model may be included in the information processing device. Other information may also be included, for example, as acquisitions, inputs, outputs, etc. For example, information to be acquired, input, output, or the like may be information obtained by processing the information, and may be, for example, a vector or an intermediate expression.

What is claimed is:

1. An information processing device comprising:
at least one memory; and
at least one processor configured to:
perform, based on input information and an environment variable, a simulation with respect to a state of a virtual world, the input information being based on an observation result of a real world, and
update the environment variable so that a result of the simulation approaches a changed state of the virtual world, the changed state being based on an observation result of the real world that is observed after the real world has changed.

2. The information processing device as claimed in claim 1, wherein the at least one processor updates the environment variable by performing backpropagation so that the result of the simulation approaches the changed state of the virtual world.

3. The information processing device as claimed in claim 1, wherein the at least one processor is further configured to:
input an output of the simulation into a first neural network to generate the result of the simulation; and
train the first neural network so that the result of the simulation approaches the changed state of the virtual world.

4. The information processing device as claimed in claim 1,
wherein the at least one processor performs the simulation based on the input information, the environment variable, and information related to a control method in the real world, and
wherein the at least one processor updates the environment variable so that the result of the simulation approaches the changed state of the virtual world, the changed state being based on the observation result of the real world that is observed after the real world is changed by control based on the control method.

5. The information processing device as claimed in claim 1, wherein the at least one processor is further configured to input the input information and the environment variable into a second neural network to output information related to a control method in the real world.

6. The information processing device as claimed in claim 5, wherein the at least one processor is further configured to train the second neural network based on the result of the simulation.

7. The information processing device as claimed in claim 1, wherein the environment variable includes information related to an object.

8. The information processing device as claimed in claim 1, wherein the input information includes the state of the virtual world.

9. The information processing device as claimed in claim 1, wherein the simulation is differentiable.

10. An information processing device comprising:
at least one memory; and
at least one processor configured to:
input a state of a virtual world and an environment variable into a first neural network to output information related to a control method;
perform, based on the state of the virtual world, the environment variable, and the information related the control method, a simulation with respect to the state of the virtual world to obtain a changed state of the virtual world, the changed state being a state to be observed after a target is controlled based on the control method; and
train the first neural network based on a result of the simulation.

11. The information processing device as claimed in claim 10, wherein the at least one processor calculates a reward based on the result of the simulation, and train the first neural network based on the reward.

12. The information processing device as claimed in claim 10, wherein the simulation is differentiable.

13. The information processing device as claimed in claim 12, wherein the at least one processor inputs an output of the simulation into a second neural network to generate the result of the simulation.

14. The information processing device as claimed in claim 10, wherein the environment variable includes information related to an object.

15. An information processing device comprising:
at least one memory; and
at least one processor configured to perform, based on input information and an environment variable, a simulation with respect to a state of a virtual world, the input information being based on an observation result of a real world,
wherein the environment variable has been updated so that a result of the simulation approaches a changed state of the virtual world, the changed state being based on an observation result of the real world that is observed after the real world has changed.

16. The information processing device as claimed in claim 15,
wherein the at least one processor is further configured to input an output of the simulation into a first neural network, and
wherein the first neural network has been trained so that the result of the simulation approaches the changed state of the virtual world.

17. The information processing device as claimed in claim 15, wherein the at least one processor performs the simulation based on the input information, the environment variable, and information related to a control method.

18. An information processing device comprising:
at least one memory; and
at least one processor configured to:
input a state of a virtual world and an environment variable into a first neural network to output information related to a control method; and
perform, based on the state of the virtual world, the environment variable, and the information related to the control method, a simulation with respect to the state of the virtual world to obtain a changed state of the virtual world, the changed state being a state to be observed after a target is controlled based on the control method.

19. A control device comprising:
at least one memory; and
at least one processor configured to:
transmit information related to an observation result of a real world to the information processing device as claimed in claim 18;
receive the information related to the control method from the information processing device; and
control an object in the real world based on the information related to the control method.

20. A device comprising:
a sensor device configured to acquire the observation result of the real world;
a drive device configured to perform drive in the real world; and
the control device as claimed in claim 19,
wherein the drive device is operated based on the information related to the control method that is obtained by the control device.
